(19) United States
(12) Patent Application Publication
(10) Pub. No.: US 2010/0155801 A1
(43) Pub. Date: Jun. 24, 2010

(54) Integrated circuit, 1T-1C embedded memory cell containing same, and method of manufacturing 1T-1C memory cell for embedded memory application

(76) Inventors: Brian S. Doyle, Portland, OR (US); Dinesh Somasekhar, Portland, OR (US); Gilbert Dewey, Hillsboro, OR (US); Satyarth Suri, Hillsboro, OR (US)

Correspondence Address: INTEL CORPORATION;c/o CPA Global, P.O. BOX 52050, MINNEAPOLIS, MN, 55402, US

(21) Appl. No.: 12/317,507

(22) Filed: Dec. 22, 2008

(51) Int. Cl. H01L 29/94; H01L 29/06; H01L 21/8242

(52) U.S. Cl. 257/301; 257/532; 438/243; 257/E21.646; 257/E29.345; 257/E29.005

(57) ABSTRACT

An integrated circuit includes a semiconducting substrate (110), electrically conductive layers (120) over the semiconducting substrate, and a capacitor (130) at least partially embedded within the semiconducting substrate such that the capacitor is entirely underneath the electrically conductive layers. A storage node voltage is on an outside layer (132) of the capacitor. In the same or another embodiment, the integrated circuit may act as a 1T-1C embedded memory cell including the semiconducting substrate, an electrically insulating stack (160) over the semiconducting substrate, a transistor (140) including a source/drain region (142) within the semiconducting substrate and a gate region (141) above the semiconducting substrate, a trench (111) extending through the electrically insulating layers and into the semiconducting substrate, a first electrically insulating layer (131) located within the trench, and the capacitor located within the trench interior to the first electrically insulating layer.

### FIELD OF THE INVENTION

The disclosed embodiments of the invention relate generally to embedded memory applications, and, in part, relate more particularly to a fully integrated transistor-based storage capacitor element capable of generating an embedded DRAM cell/array.

### BACKGROUND OF THE INVENTION

Dynamic random access memory (DRAM) is used in a variety of computer systems and applications due, at least in part, to its simple single-transistor, single-capacitor (1T-1C) structure that allows it to achieve a high density. Existing processes use a trench capacitor that is fabricated before the transistor is formed and suffer from a thicker oxide due to front-end processing conditions. Alternative processes currently in use fabricate the capacitor in the interconnect system, causing disruption in the global routing lines.

### BRIEF DESCRIPTION OF THE DRAWINGS

The disclosed embodiments will be better understood from a reading of the following detailed description, taken in conjunction with the accompanying figures in the drawings in which:

FIGS. 1 and 2 are cross-sectional views of an integrated circuit according to an embodiment of the invention; and

FIG. 3 is a flowchart illustrating a method of manufacturing a 1T-1C memory cell for an embedded memory application according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements, while similar reference numerals may, but do not necessarily, denote similar elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, an integrated circuit comprises a semiconducting substrate, electrically conductive layers over the semiconducting substrate, and a capacitor at least partially embedded within the semiconducting substrate such that the capacitor is entirely underneath the electrically conductive layers. A storage node voltage is on an outside layer of the capacitor. In the same or another embodiment, a 1T-1C embedded memory cell comprises a semiconducting substrate, an electrically insulating stack over the semiconducting substrate, a transistor comprising a source/drain region within a first section of the semiconducting substrate and a gate region above the semiconducting substrate, a trench extending through the electrically insulating layers and into a second section of the semiconducting substrate that is adjacent to the first section of the semiconducting substrate, a first electrically insulating layer located within the trench, and a capacitor comprising: a first electrically conductive layer located within the trench interior to the first electrically insulating layer; a second electrically insulating layer located within the trench interior to the first electrically conductive layer; and a second electrically conductive layer located within the trench interior to the second electrically insulating layer.

Earlier attempts to fabricate the cell capacitor after the transistor involved maintaining a tri-gate transistor fin throughout the processing but suffered from several processing issues. These include at least some of the following: (1) to get sufficient capacitance the fin (initial silicon) etch has to be extremely deep (˜0.5 microns (μm)); (2) the shallow trench isolation (STI) oxide fill is very difficult to perform without leaving voids in the trenches; (3) the fin itself needs to survive the aggressive high-powered oxide etch process; (4) the cell size depends on the alignment of the capacitor cell with the polysilicon (mis-alignment in the x-dimension causes the capacitor size to change since the fin itself survives the etch process); and (5) the presence of the fin complicates the trench fill process because the distance between the capacitor sidewall and the fin sidewall has to incorporate outer metal/insulator/inner metal/insulator/outer metal (at least 5 layers), and this will be more difficult as the cell size decreases or as mis-alignment in the y-dimension moves the fin toward the middle of the cell.

Embodiments of the invention enable the post-transistor formation of high capacitance cells without requiring ultra-deep trenches and without disturbing the global routing lines in the interconnect system. Furthermore, since embodiments of the invention eliminate most (or all) of the transistor fin, the foregoing and other problems associated with the presence of the fin are also eliminated. A result is the integration of a DRAM memory element formation with a logic technology process suitable for a high volume manufacturing environment.

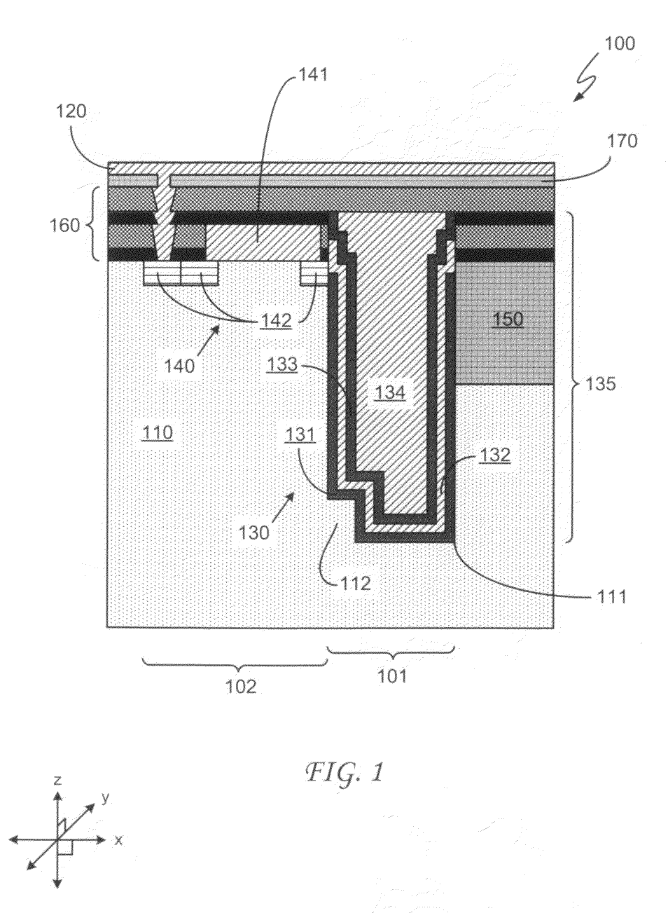

Referring now to the drawings, FIG. 1 is a cross-sectional view of an integrated circuit 100 according to an embodiment of the invention. As illustrated in FIG. 1, integrated circuit 100 comprises a semiconducting substrate 110, an electrically conductive layer 120 over semiconducting substrate 110, and a capacitor 130 at least partially embedded within a section 101 of semiconducting substrate 110 such that capacitor 130 is entirely underneath electrically conductive layer 120. A capacitor integrated underneath an integrated circuit's metal layers would have utility in a variety of applications, and capacitor 130 may therefore be useful as a coupling capacitor or a decoupling capacitor, among other uses. The use of capacitor 130 in an embedded memory application will be discussed below.

In the illustrated embodiment, semiconducting substrate 110 contains a trench 111 in which at least a portion of capacitor 130 is located. Capacitor 130 comprises an electrically insulating layer 131 at least partially located within trench 111, an electrically conductive layer 132 at least partially located within trench 111 interior to electrically insulating layer 131, an electrically insulating layer 133 at least partially located within trench 111 interior to electrically conductive layer 132, and an electrically conductive layer 134 at least partially located within trench 111 interior to electrically insulating layer 133. A storage node voltage is on electrically conductive layer 132. Trench 111, and therefore capacitor 130, descends within semiconducting substrate 110 to a depth 135, the magnitude of which may be adjusted as a means of adjusting the capacitance of capacitor 130. In general, increasing the depth of trench 111 (i.e., increasing the magnitude of depth 135) results in greater capacitance for capacitor 130. However, for reasons explained below, the configuration of capacitor 130 allows depth 135 to be reduced compared to what is required for other configurations.

Trench 111 also contains a fin 112 that is an artifact left over from the transistor formation process. Several problems associated with maintaining the transistor fin at its original height were detailed above; in the illustrated embodiment, fin 112 has been shortened to the point where its presence does not create manufacturing challenges. Some (non-illustrated) embodiments, in fact, remove fin 112 altogether. Among other things, the substantial or complete removal of fin 112 means that the processing issues detailed above are no longer problematic.

In one embodiment, capacitor 130 has an aspect ratio of at least 2:1. In the same or another embodiment, electrically insulating layer 131 comprises a nitride layer. In the same or another embodiment, electrically insulating layer 133 comprises a high-k dielectric layer. (As used herein, the phrase “high-k” refers to materials having a dielectric constant, k, greater than that of silicon dioxide, that is, greater than about 4.) Integrated circuit 100 further comprises a gate region 141 and source/drain regions 142 of a transistor 140, STI region 150, dielectric layers 160, and etch stop layer 170. Transistor 140 is located within and above a section 102 of semiconducting substrate 110. As illustrated, section 102 is adjacent to section 101 that contains at least a portion of capacitor 130. In one embodiment, transistor 140 and capacitor 130 can be used as part of an embedded memory cell, as will be further discussed below.

Referring still to FIG. 1, integrated circuit 100 will again be introduced, this time emphasizing its manifestation as a 1T-1C embedded memory cell. As previously discussed (albeit in a slightly different context), the 1T-1C embedded memory cell comprises capacitor 130 and transistor 140 located side-by-side in (or partially within) semiconducting substrate 110 and the overlying electrically insulating stack made up of dielectric layers 160 and etch stop layer(s) 170 (e.g., nitride/oxide etch stop layer(s), gate etch stop layer(s)). Note that electrically conductive layer 132 is electrically connected to source/drain region 142 of transistor 140. Note also that electrically conductive layer 132, i.e., the outside conductive layer, acts as a storage node of the 1T-1C embedded memory cell. This configuration provides a relatively high dielectric constant for electrically conductive layer 133, allowing depth 135 to be reduced compared to what is required for other configurations. It should also be noted that electrically insulating layer 131 prevents electrical shorting of the storage node to semiconducting substrate 110.

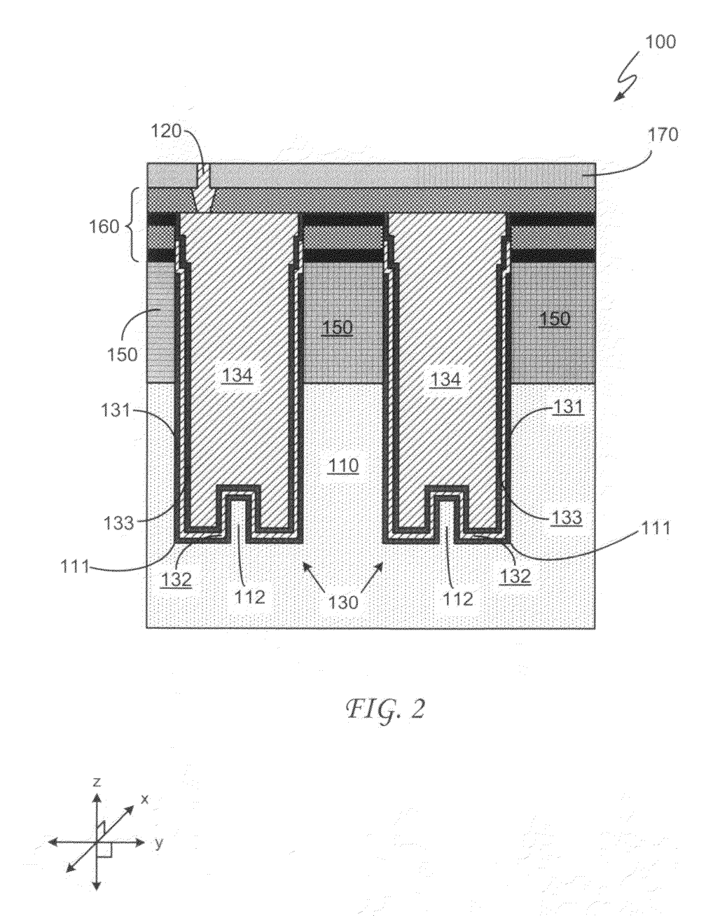

The coordinate system shown in FIG. 1 indicates that the FIG. 1 illustration depicts integrated circuit 100 as seen in cross section in the x-dimension. FIG. 2, which, like FIG. 1, is a cross-sectional view of integrated circuit 100 according to an embodiment of the invention, depicts integrated circuit 100 as seen in cross section in the y-dimension.

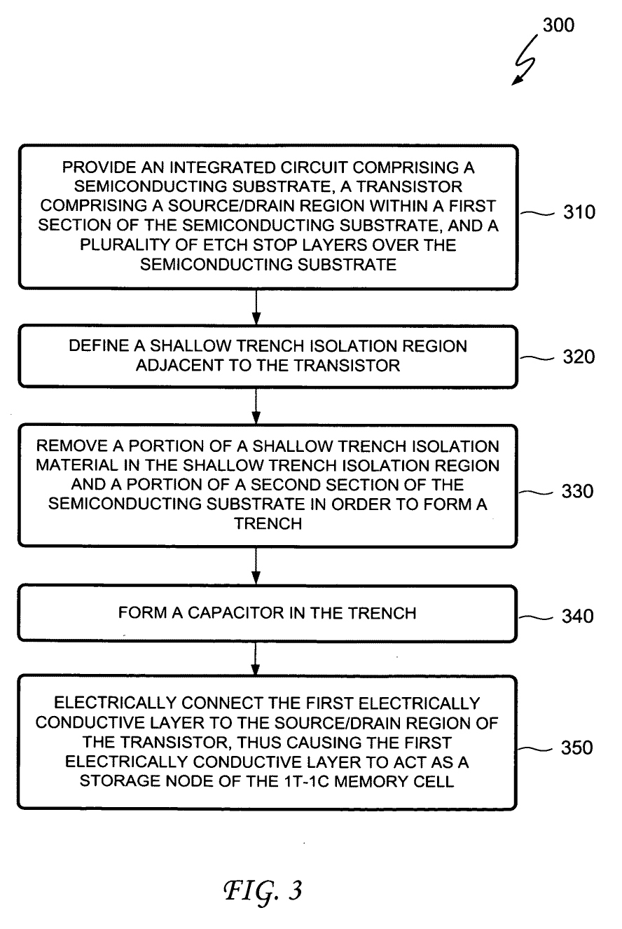

FIG. 3 is a flowchart illustrating a method 300 of manufacturing a 1T-1C memory cell for an embedded memory application according to an embodiment of the invention. Method 300 describes a post-transistor process flow to generate an embedded DRAM (eDRAM) cell capacitor. As will become apparent from the following, method 300 forms the capacitor cell deep within the silicon substrate using a metal/high-k dielectric/metal stack. As an example, method 300 may result in the formation of a 1T-1C embedded memory cell that is similar to integrated circuit 100 that is shown in FIGS. 1 and 2.

A step 310 of method 300 is to provide an integrated circuit comprising a semiconducting substrate, a transistor comprising a source/drain region within a first section of the semiconducting substrate, and a plurality of etch stop layers over the semiconducting substrate. As an example, the semiconducting substrate and the etch stop layers can be similar to, respectively, semiconducting substrate 110 and dielectric layers 160 that are shown in FIGS. 1 and 2. As another example, the transistor can be similar to transistor 140 and the source/drain region can be similar to source/drain region 142, both of which are shown in FIG. 1.

A step 320 of method 300 is to define a shallow trench isolation region adjacent to the transistor. As an example, the shallow trench isolation region can be similar to shallow trench isolation region 150 that is shown in FIGS. 1 and 2. In one embodiment, step 320 is the standard shallow trench isolation of the logic devices, and represents the initial silicon etch of method 300. This is followed by an oxide fill, which is the standard STI fill.

A step 330 of method 300 is to remove a portion of a shallow trench isolation material (e.g., STI oxide) in the shallow trench isolation region and a portion of a second section of the semiconducting substrate in order to form a trench. As an example, the second section of the semiconducting substrate can be similar to section 101 of semiconducting substrate 110 that is shown in FIG. 1. As another example, the trench can be similar to trench 111 that is shown in FIGS. 1 and 2. In one embodiment, step 330 results in the trench having an aspect ratio of at least 2:1. Following the fabrication of the transistor, the capacitor etch (i.e., the etch that forms the trench in which the capacitor is later formed) performed in step 330 is partly an oxide etch until the STI oxide is cleared, and then it is a silicon etch. In other words, the capacitor etch removes both silicon (from the first section of the semiconducting substrate) and oxide (from the STI region in the second section of the semiconducting substrate). The oxide etch is a high powered etch, which etches some of the transistor fin down. The final silicon etch is selective to the oxide material on top and etches most (or all) of the remaining fin away, leaving a space (in the trench) for the capacitor that is much larger and much easier to fill than the space would be if the fin were maintained throughout the capacitor formation process.

A step 340 of method 300 is to form a capacitor in the trench. As an example, the capacitor can be similar to capacitor 130 that is shown in FIGS. 1 and 2. In one embodiment, step 340 comprises filling the trench with a MIM structure. In a particular embodiment, filling the trench with the MIM structure comprises forming a first insulating layer in the trench then etching back to uncover the transistor junction, forming a first electrically conductive layer in the trench, forming a second electrically insulating layer in the trench interior to the first electrically conductive layer, and forming a second electrically conductive layer in the trench interior to the second electrically insulating layer. As an example, the first electrically insulating layer, the first electrically conductive layer, the second electrically insulating layer, and the second electrically conductive layer can be similar to, respectively, electrically insulating layer 131, electrically conductive layer 132, electrically insulating layer 133, and electrically conductive layer 134, all of which are shown in FIGS. 1 and 2.

A step 350 of method 300 is to electrically connect the first electrically conductive layer to the source/drain region of the transistor, thus causing the first electrically conductive layer to act as a storage node of the 1T-1C memory cell.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the 1T-1C embedded memory cell and the related structures and methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. An integrated circuit comprising:
a semiconducting substrate;
an electrically conductive layer over the semiconducting substrate; and
a capacitor at least partially embedded within the semiconducting substrate such that the capacitor is entirely underneath the electrically conductive layer,
wherein:
the capacitor comprises an outside layer; and
a storage node voltage is on the outside layer of the capacitor.

2. The integrated circuit of claim 1 wherein:
the semiconducting substrate contains a trench;
at least a portion of the capacitor lies within the trench; and
the capacitor comprises:
a first electrically insulating layer at least partially located within the trench;
a first electrically conductive layer at least partially located within the trench interior to the first electrically insulating layer, the first electrically conductive layer being the outside layer of the capacitor;
a second electrically insulating layer at least partially located within the trench interior to the first electrically conductive layer; and
a second electrically conductive layer at least partially located within the trench interior to the second electrically insulating layer.

3. The integrated circuit of claim 2 wherein:
the first electrically insulating layer comprises a nitride layer.

4. The integrated circuit of claim 3 wherein:
the second electrically insulating layer comprises a high-k dielectric layer.

5. The integrated circuit of claim 1 wherein:
the capacitor has an aspect ratio of at least 2:1.

6. A 1T-1C embedded memory cell comprising:
a semiconducting substrate;
an electrically insulating stack over the semiconducting substrate;
a transistor comprising a source/drain region within a first section of the semiconducting substrate and a gate region above the semiconducting substrate;
a trench extending through the electrically insulating stack and into a second section of the semiconducting substrate that is adjacent to the first section of the semiconducting substrate;
a first electrically insulating layer located within the trench;
a first electrically conductive layer located within the trench interior to the first electrically insulating layer;
a second electrically insulating layer located within the trench interior to the first electrically conductive layer; and
a second electrically conductive layer located within the trench interior to the second electrically insulating layer.

7. The 1T-1C embedded memory cell of claim 6 wherein:
the first electrically conductive layer is electrically connected to the source/drain region of the transistor.

8. The 1T-1C embedded memory cell of claim 6 wherein:
the trench has an aspect ratio of at least 2:1.

9. The 1T-1C embedded memory cell of claim 6 wherein:
the first electrically insulating layer comprises a nitride layer.

10. The 1T-1C embedded memory cell of claim 6 wherein:
the second electrically insulating layer comprises a high-k dielectric layer.

11. The 1T-1C embedded memory cell of claim 6 wherein:
the first electrically conductive layer acts as a storage node of the 1T-1C embedded memory cell.

12. A method of manufacturing a 1T-1C memory cell for an embedded memory application, the method comprising:
providing an integrated circuit comprising:
a semiconducting substrate;
a transistor comprising a source/drain region within a first section of the semiconducting substrate; and
a plurality of electrically insulating layers over the semiconducting substrate;
defining a shallow trench isolation region adjacent to the transistor;
removing a portion of a shallow trench isolation material in the shallow trench isolation region and a portion of a second section of the semiconducting substrate in order to form a trench; and
forming a capacitor in the trench.

13. The method of claim 12 wherein:
forming the capacitor comprises filling the trench with a MIM structure.

14. The method of claim 13 wherein:
filling the trench with the MIM structure comprises:
forming a first electrically conductive layer in the trench;
forming a first electrically insulating layer in the trench interior to the first electrically conductive layer; and
forming a second electrically conductive layer in the trench interior to the first electrically insulating layer.

15. The method of claim 14 wherein:
forming the first electrically insulating layer comprises forming a high-k dielectric layer.

16. The method of claim 14 wherein:
forming the capacitor further comprises filling the trench with a second electrically insulating layer; and
the second electrically insulating layer is exterior to the first electrically conductive layer.

17. The method of claim 16 wherein:
filling the trench with the second electrically insulating layer comprises filling the trench with a nitride layer.

18. The method of claim 12 further comprising:
electrically connecting the first electrically conductive layer to the source/drain region of the transistor, thus causing the first electrically conductive layer to act as a storage node of the 1T-1C memory cell.

19. The method of claim 12 wherein:
removing the portion of the shallow trench isolation region and the portion of the second section of the semiconducting substrate results in the trench having an aspect ratio of at least 2:1.
